(19) United States
(12) Patent Application Publication
(10) Pub. No.: US 2010/0090342 A1
(43) Pub. Date: Apr. 15, 2010

(54) Metal Line Formation Through Silicon/Germanium Soaking

(76) Inventors: Hui-Lin Chang, Hsin-Chu (TW); Chih-Lung Lin, Taipei (TW); Syun-Ming Jang, Hsin-Chu (TW)

Correspondence Address: SLATER & MATSIL, L.L.P., 17950 PRESTON ROAD, SUITE 1000, DALLAS, TX, 75252, US

(21) Appl. No.: 12/251,974

(22) Filed: Oct. 15, 2008

(51) Int. Cl. H01L 23/52; H01L 21/4763

(52) U.S. Cl. 257/751; 438/627; 257/E23.141; 257/E21.495

(57) ABSTRACT

A method for forming interconnect structure includes providing a substrate; forming a low-k dielectric layer over the substrate; forming an opening in the low-k dielectric layer; after the step of forming the opening, performing a silicon/germanium soaking process to exposed surfaces of the low-k dielectric layer; and after the silicon/germanium soaking process, filling the opening.

### TECHNICAL FIELD

This invention is related generally to integrated circuits, and more particularly, to the methods for forming interconnect structures in integrated circuits.

### BACKGROUND

A conventional integrated circuit contains a plurality of patterns of metal lines separated by inter-wiring spacings and a plurality of interconnect lines, such as bus lines, bit lines, word lines and logic interconnect lines. Typically, the metal patterns of vertically spaced metallization layers are electrically interconnected by vias. Metal lines formed in trench-like openings typically extend substantially parallel to the semiconductor substrate. Semiconductor devices of such type, according to current technology, may comprise eight or more levels of metallization layers to satisfy device geometry and micro-miniaturization requirements.

A common method for forming metal lines or plugs is known as “damascene.” Generally, this process involves forming openings in the inter-metal dielectric (IMD) layers, which separates the vertically spaced metallization layers. The openings are typically formed using conventional lithographic and etching techniques. After the openings are formed, the openings are filled with copper or copper alloys. Excess metal material on the surface of the respective dielectric layer is then removed by chemical mechanical planarization (CMP).

FIG. 1 illustrates a cross-sectional view of a conventional interconnection structure 100 formed using a damascene process. Metal lines 102 and 104, which are typically formed of copper or copper alloys, are interconnected by via 110. IMD 108 separates the two dielectric layers where metal lines 102 and 104 are located. Etch stop layer (ESL) 105 is formed on copper line 102. Diffusion barrier layers 112 and 114 are formed to prevent copper from diffusing into surrounding low-k dielectric materials.

With the increasing down-scaling of integrated circuits, the formation of the interconnect structure as shown in FIG. 1 starts to suffer from void formation. With width W1 of metal line 104 and width W2 of via 110 being small, voids, for example, void 116 may be formed in metal line 104 and via 110. This not only causes the increase in the current densities that needs to be carried by metal line 104 and via 110, but also causes the degradation of the reliability of the interconnect structure. Further, if the voids are exposed through the top surface of metal line 104 after the CMP, the subsequently formed features, such as an etch stop layer or a low-k material (not shown), may fall into the voids, and hence the integrity of the subsequently formed features is degraded. Therefore, in order to reduce the void formation in the interconnect structures and improve the quality of the interconnect structures, a new formation method is needed.

### SUMMARY OF THE INVENTION

In accordance with one aspect of the present invention, a method for forming interconnect structure includes providing a substrate; forming a low-k dielectric layer over the substrate; forming an opening in the low-k dielectric layer; after the step of forming the opening, performing a silicon/germanium soaking process to exposed surfaces of the low-k dielectric layer; and after the silicon/germanium soaking process, filling the opening.

In accordance with another aspect of the present invention, a method for forming a circuit structure includes providing a substrate; forming a low-k dielectric layer over the substrate; forming an opening in the low-k dielectric layer; after the step of forming the opening, performing a silicon soaking process to exposed surfaces of the low-k dielectric layer to form a silicon-rich layer; and after the silicon soaking process, filling the opening with a metallic material contacting the silicon-rich layer, wherein the metallic material is free from a barrier layer.

In accordance with yet another aspect of the present invention, a method for forming a circuit structure includes providing a substrate; forming a low-k dielectric layer over the substrate; forming an opening in the low-k dielectric layer; after the step of forming the opening, performing a silicon/germanium soaking process to exposed surfaces of the low-k dielectric layer; after the silicon/germanium soaking process, forming a barrier layer on the exposed surfaces of the low-k dielectric layer; and filling the opening with a metallic material, wherein the metallic material is over the barrier layer.

In accordance with yet another aspect of the present invention, a circuit structure includes a substrate; a low-k dielectric layer over the substrate; a conductor in the low-k dielectric layer; and a silicon/germanium rich layer between the low-k dielectric layer and the conductor.

In accordance with yet another aspect of the present invention, a circuit structure includes a substrate; a low-k dielectric layer over the substrate; an opening in the low-k dielectric layer; a silicon/germanium rich layer in the opening and contacting the low-k dielectric layer, wherein the silicon/germanium rich layer has a greater silicon concentration than the low-k dielectric layer; and a copper line in the opening and contacting the silicon/germanium rich layer.

With the silicon/germanium soaking step performed to the damascene opening before the step of filling the damascene openings, the properties of the low-k dielectric materials are improved, resulting in improved barrier formation and improved gap filling.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional interconnect structure comprising a damascene structure;

FIGS. 2 through 8 are cross-sectional views of intermediate stages in the manufacture of an interconnect structure; and

FIG. 9 shows the number of voids in different regions of wafers, where the results of wafers whose interconnect structures are formed using the silicon-soaking process are compared to the results of a wafer whose interconnect structures are formed without the silicon-soaking process.

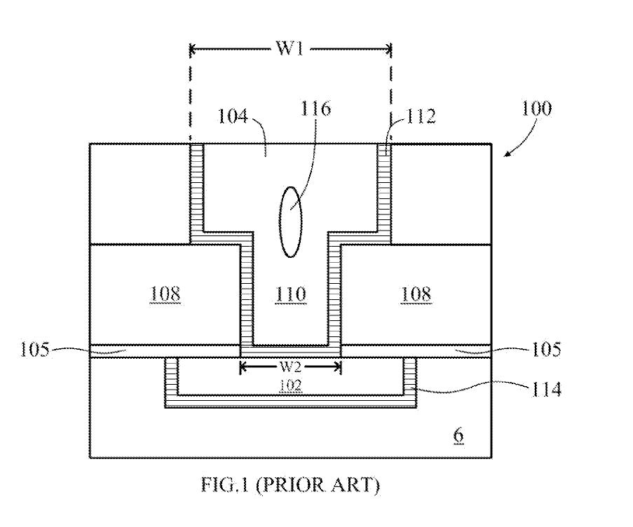

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for forming an interconnect structure in a low-k dielectric layer is provided. The intermediate stages for manufacturing the preferred embodiment of the present invention are illustrated. Variations of the preferred embodiments are then discussed. Throughout the various views and illustrative embodiments of the present invention, like reference numbers are used to designate like elements.

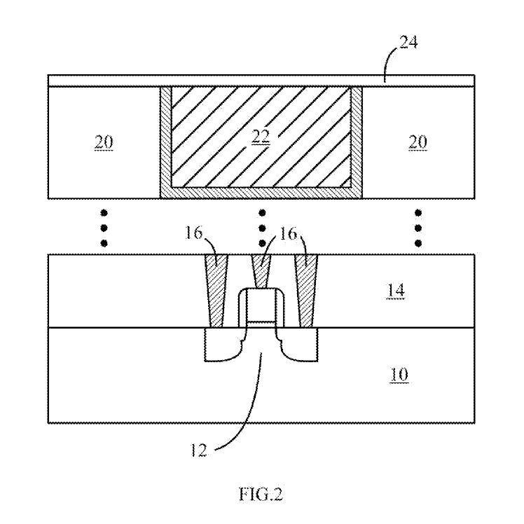

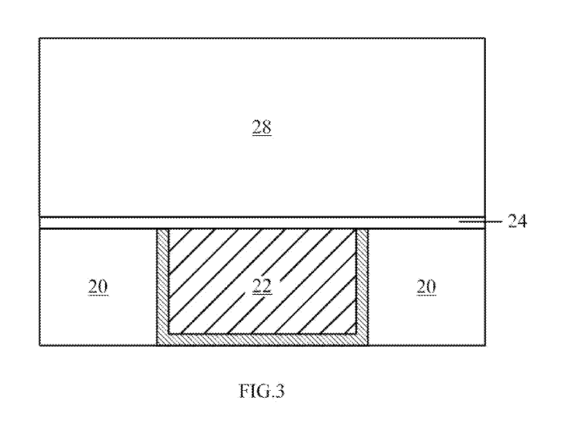

FIG. 2 illustrates a starting structure including substrate 10. Substrate 10 may be formed of commonly used semiconductor materials such as silicon, silicon germanium, or the like, and may be a bulk substrate or a semiconductor-on-insulator substrate. Active circuit 12, which is symbolized using a transistor, may be formed at a surface of substrate 10. As is known in the art, inter-layer dielectric (ILD) 14 may be formed to cover active circuit 12. Contact plugs 16 may be formed to connect active circuit 12 to the overlying interconnect structure, as will be discussed in the subsequent paragraphs. The interconnect structure also has the function of interconnecting active circuit 12, and connecting active circuit 12 to bond pads (not shown) formed at the surface of the respective semiconductor chip. For simplicity, substrate 10, active circuit 12, ILD 14, and contact plugs 16 are not shown in subsequent drawings.

The interconnect structure may include one or more metallization layers. Referring again to FIG. 2, an exemplary metallization layer includes conductive line 22 in dielectric layer 20. Conductive line 22 is preferably a metal line comprising copper, tungsten, aluminum, silver, gold, alloys thereof, compounds thereof, and combinations thereof. Conductive line 22 is typically connected to another underlying feature (not shown), such as a via or one of contact plugs 16. Dielectric layer 20 is commonly known in the art as an inter-metal dielectric (IMD), and preferably has a low k value, for example, less than about 2.5.

Etch stop layer (ESL) 24 is formed on dielectric layer 20 and conductive line 22. Preferably, ESL 24 comprises nitrides, silicon-carbon based materials, carbon-doped oxides, or combinations thereof. The preferred formation method is plasma enhanced chemical vapor deposition (PECVD). However, other commonly used methods such as high-density plasma CVD (HDPCVD), atomic layer CVD (ALCVD), and the like, can also be used.

In alternative embodiments, dielectric layer 24 is a diffusion barrier layer preventing undesirable elements, such as copper, from diffusing into the subsequently formed low-k dielectric layer (dielectric layer 28 in FIG. 3). In a more preferred embodiment, dielectric layer 24 acts as both an etch stop layer and a diffusion barrier layer.

FIG. 3 illustrates the formation of a low-k dielectric layer 28. Part of the function of low-k dielectric layer 28 is to provide insulation between conductive line 22 and overlying conductive lines that will be formed subsequently. Accordingly, low-k dielectric layer 28 is sometimes referred to as an inter-metal dielectric (IMD) layer.

Low-k dielectric layer 28 preferably has a dielectric constant (k) value of lower than about 3.5, and more preferably lower than about 2.5. The preferred materials include carbon-containing materials, organo-silicate glass, porogen-containing materials, and combinations thereof. Low-k dielectric layer 28 may be deposited using a chemical vapor deposition (CVD) method, preferably PECVD, although other commonly used deposition methods, such as low pressure CVD (LPCVD), ALCVD, and spin-on, can also be used.

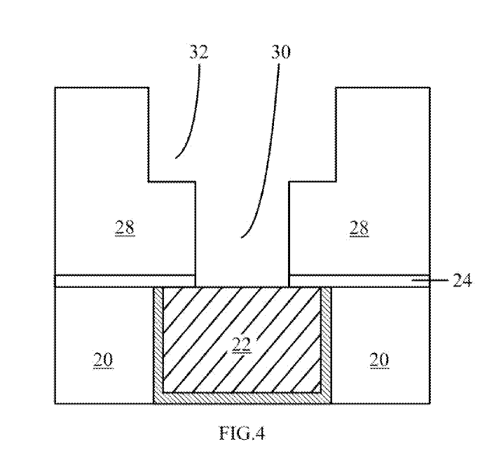

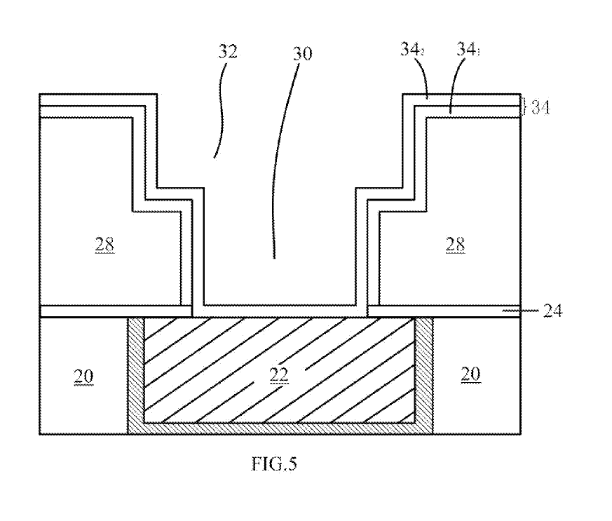

FIG. 4 illustrates the formation of via opening 30 and trench opening 32 in low-k dielectric layer 28. Photo resists (not shown) may be formed and patterned over low-k dielectric layer 28 to aid the formation of via opening 30 and trench opening 32. In the preferred embodiment, an anisotropic etch cuts through low-k dielectric layer 28 and stops at ESL 24, thereby forming via opening 30. Trench opening 32 is then formed. Since there is no etch stop layer for stopping the etching of trench opening 32, etching time is controlled so that the etching of the trench opening 32 stops at a desired depth. In alternative embodiments, a trench-first approach is taken, in which trench opening 32 is formed prior to the formation of via opening 30. ESL 24 is then etched through via opening 30, exposing underlying conductive line 22.

In alternative embodiments, the previously discussed low-k dielectric layer 28 may be replaced by a first low-k dielectric layer, an ESL on the first low-k dielectric layer, and a second low-k dielectric layer on the ESL. The ESL is used for stopping the etching for forming trench opening 32. One skilled in the art will realize the appropriate process steps.

After the formation of openings 30 and 32, a pre-clean may be performed. The pre-clean may include dry etching for removing the polymer generated by etching low-k dielectric layer 28. As a side effect, the etching of low-k dielectric layer 28 and the pre-clean cause carbon to be depleted from low-k dielectric layer 28, especially from the exposed surface portions. This not only causes the generation of dangling bonds on the exposed surface portions, hence the instability of low-k dielectric layer 28, but also results in the degradation of the wettability of low-k dielectric layer 28.

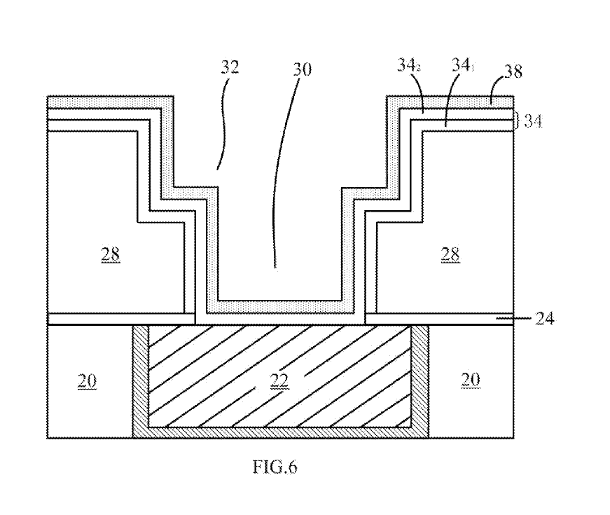

Referring to FIG. 5, after the pre-clean, a silicon/germanium soaking process is performed to the exposed surfaces of low-k dielectric layer 28. Throughout the description, the term “silicon/germanium soaking” refers to a soaking process performed in an environment either containing a silicon-containing gas, a germanium-containing gas, or gases containing both silicon and germanium. In an embodiment, the silicon/germanium soaking process is performed using remote plasma. Since the remote plasma is substantially non-directional, the sidewall portions and the bottom portions of openings 30 and 32 may be soaked more uniformly. In other embodiments, the silicon/germanium soaking process is performed using (local) plasma. In yet other embodiments, thermal silicon/germanium soaking is used. The process gases include silicon-containing gases, such as SiH₄, Si₂H₆, tetramethylsilane (4MS), trimethylsilane (3MS), and/or the like, and combinations thereof. Alternatively, the process gases include germanium-containing gases, such as GeH₄ and/or the like, or the combinations of the silicon-containing gases and the germanium-containing gases. In an exemplary embodiment, the process conditions include a process temperature of about 100° C. to about 400° C. and a process gas pressure of between about 1 mtorr to about 1 torr. The silicon/germanium soaking time may be between about 1 second to about 10 minutes. In addition, carrier gases such as inert gases, nitrogen, hydrogen, ammonia, and combinations thereof may be used.

The silicon/germanium soaking process causes the decomposition of the silicon-containing and/or germanium-containing gases, so that silicon and/or germanium are deposited to the surface of the exposed low-k dielectric layer 28, forming silicon/germanium rich layer 34. The term “silicon/germanium rich” indicates silicon rich, germanium rich, or both silicon rich and germanium rich. Silicon and germanium may react with the surface portion of the porous low-k dielectric material, and combine with the dangling bonds that were generated in the formation of openings 30 and 32 and the pre-clean step. Accordingly, silicon/germanium rich layer 34 includes sub layer 34₁, which is the resultant layer of bonding silicon/germanium to low-k dielectric layer 28. Further, silicon/germanium rich layer 34 may also include an additional silicon/germanium layer 34₂ that is not reacted with low-k dielectric layer 28, and hence is a separate layer. Further, silicon/germanium rich layer 34 has a silicon/germanium concentration greater than the silicon concentration of inner portions of low-k dielectric layer 28 by, for example, greater than about 20 percent. During the silicon/germanium soaking process, silicon or germanium may also be deposited on conductive line 22. Since silicon/germanium rich layer 34 is conductive and can intermix with conductive line 22 in the subsequent thermal budget, there is no need to remove the portion of silicon/germanium rich layer 34 formed on conductive line 22.

Optionally, particularly in the case the subsequent barrier layer (not shown in FIG. 5, refer to FIG. 6) contains nitrogen, a nitrogen treatment may be performed to add nitrogen into low-k dielectric layer 28, so that a better adhesion between low-k dielectric layer 28 and the nitrogen-containing barrier layer may be achieved. The nitrogen treatment may be performed in an environment containing a nitrogen-containing gas, such as N₂. The nitrogen treatment may be a thermal treatment. It is noted that the nitrogen treatment, if performed, needs to be after the step of the silicon/germanium soaking process. Otherwise, the nitrogen treatment will prevent silicon or germanium from being mixed or bonded with conductive line 22.

FIG. 6 illustrates the formation of barrier layer 38, which prevents copper from diffusing into low-k dielectric layer 28. Barrier layer 38 may be formed of a material comprising titanium, titanium nitride, tantalum, tantalum nitride, or the like, and may be formed using a PVD or a chemical vapor deposition (CVD) method such as atomic layer CVD. It may be a single layer or a composite layer. The silicon/germanium soaking process has several advantageous features for the formation of barrier layer 38. First, since the surface structure of low-k dielectric layer 28 is improved, the clouding effects, which cause the atoms of the barrier layer 38 to penetrate into the pores of low-k dielectric layer 28, are reduced. Second, the wettability of low-k dielectric layer 28 is improved, and hence resulting in a more conformal barrier layer 38.

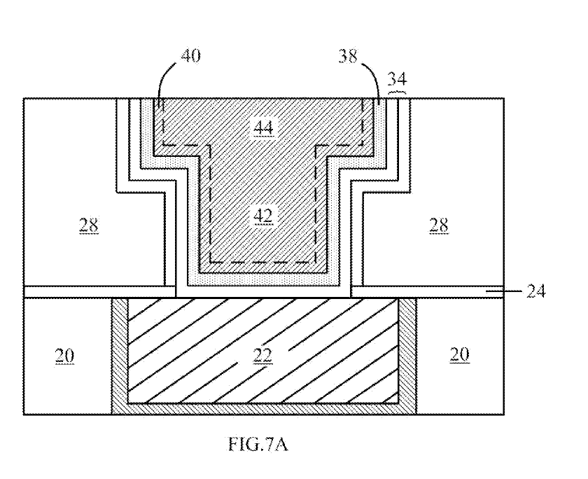

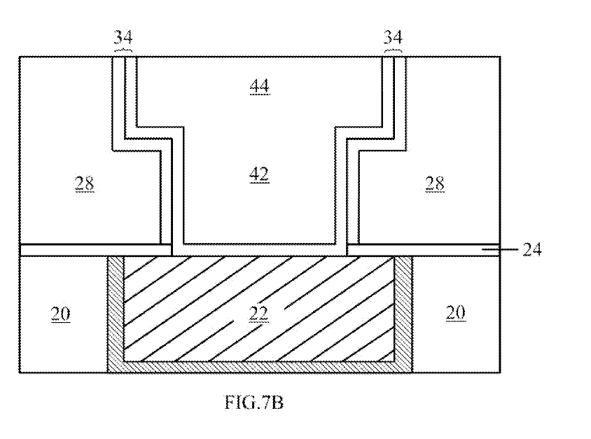

Referring to FIG. 7A, via opening 30 and trench opening 32 are filled with a metallic material, preferably copper or copper alloys. However, other metals and metal alloys such as aluminum, tungsten, silver and gold can also be used. The filling process may include forming seed layer 40, for example, using electroless plating or PVD, and then plating the metallic material into the remaining portions of openings 30 and 32. Seed layer 40 may include essentially the same material as the metallic material, and hence is not shown in the subsequent drawings. A chemical mechanical polish (CMP) is then performed to remove excess portions of the metallic material, resulting in via 42 and metal line 44. Since the conformity of barrier layer 38 has been improved by the silicon/germanium soaking process, the metallic material may be filled into openings 30 and 32 more uniformly. The possibility that voids are generated in via 42 and metal line 44 is thus reduced.

Referring to FIG. 7B, since silicon/germanium rich layer 34 is more resistant to the copper diffusion, the formation of barrier layer 38 may be skipped, and via 42 and metal line 44 may be in physical contact with silicon/germanium rich layer 34. In this case, the possibility that copper diffuses into low-k dielectric layer 28 is reduced by silicon/germanium rich layer 34.

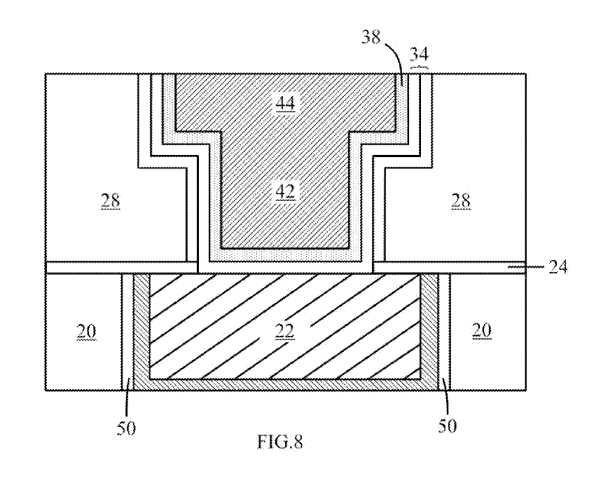

The previously discussed embodiment illustrates the formation of a dual damascene structure. Silicon/germanium rich layers can also be formed for single damascene structures. FIG. 8 illustrates silicon/germanium rich layer 50 formed in a single damascene structure, which may be formed using essentially the same method as discussed in preceding paragraphs.

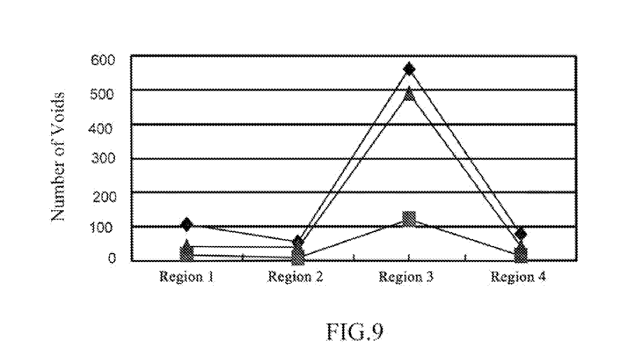

Due to the formation of silicon/germanium rich layer 34, the mechanical and electrical properties of low-k dielectric layer 28 are improved. Silicon/germanium rich layer 34 has better adhesion to the overlying barrier layer 38 or copper than low-k dielectric layer 28, and thus the possibility of void formation is reduced. FIG. 9 illustrates experiment results showing the number of voids in different regions (regions 1, 2, 3, and 4) of wafers, wherein diamonds indicate the number of voids on a wafer whose interconnect structure was formed without going through the silicon/germanium soaking process, and triangles and squares indicate the numbers of voids on wafers whose interconnect structures were formed using the silicon/germanium soaking. FIG. 9 shows that the numbers of voids may be reduced by using the silicon/germanium soaking process, and the reduction in the number of voids was observed on multiple regions of the wafers.

Further experiment results (not shown) also revealed that the silicon/germanium soaking process resulted in the improvement in the electrical property of the interconnect structures. It was found that by using the silicon/germanium soaking process, the capacitance between the metal lines may be reduced.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming a circuit structure, the method comprising:
providing a substrate;
forming a low-k dielectric layer over the substrate;
forming an opening in the low-k dielectric layer;
after the step of forming the opening, performing a silicon/germanium soaking process to exposed surfaces of the low-k dielectric layer; and
after the silicon/germanium soaking process, filling the opening.

2. The method of claim 1, wherein the step of filling the opening comprises forming a diffusion barrier layer to cover the low-k dielectric layer, and filling a metallic material over the diffusion barrier layer.

3. The method of claim 2, wherein the step of forming the diffusion barrier layer is performed using physical vapor deposition.

4. The method of claim 1, wherein the step of filling the opening is free from a step of forming a barrier layer over the low-k dielectric layer.

5. The method of claim 1, wherein the silicon/germanium soaking process comprises remote plasma soaking.

6. The method of claim 1, wherein the step of the silicon/germanium soaking process comprises local plasma soaking.

7. The method of claim 1, wherein the step of the silicon/germanium soaking process comprises thermal soaking.

8. The method of claim 1, wherein the silicon/germanium soaking process is performed in an environment containing a silicon-containing gas.

9. The method of claim 1, wherein the silicon/germanium soaking process is performed in an environment containing a germanium-containing gas.

10. The method of claim 1 further comprising, after the step of forming the opening and before the step of filling the opening, performing a nitrogen treatment.

11. The method of claim 10, wherein the step of performing the nitrogen treatment is after the step of performing the silicon/germanium soaking process.

12. A method for forming a circuit structure, the method comprising:
providing a substrate;
forming a low-k dielectric layer over the substrate;
forming an opening in the low-k dielectric layer;
after the step of forming the opening, performing a silicon soaking process to exposed surfaces of the low-k dielectric layer to form a silicon-rich layer; and
after the silicon soaking process, filling the opening with a metallic material contacting the silicon-rich layer, wherein the metallic material is free from a barrier layer.

13. The method of claim 12, wherein the step of filling the opening comprises:
forming a seed layer contacting the silicon-rich layer; and
filling remaining portions of the opening.

14. The method of claim 12, wherein the step of performing the silicon soaking process comprises a method selected from the group consisting essentially of local plasma treatment, remote plasma treatment, and thermal treatment.

15. A method for forming a circuit structure, the method comprising:
providing a substrate;
forming a low-k dielectric layer over the substrate;
forming an opening in the low-k dielectric layer;
after the step of forming the opening, performing a silicon/germanium soaking process to exposed surfaces of the low-k dielectric layer;
after the silicon/germanium soaking process, forming a barrier layer on the exposed surfaces of the low-k dielectric layer; and
filling the opening with a metallic material, wherein the metallic material is over the barrier layer.

16. The method of claim 15, wherein the metallic material is selected from the group consisting essentially of tantalum, tantalum nitride, titanium, titanium nitride, and combinations thereof.

17. The method of claim 15 further comprising, after the step of forming the opening and before the step of forming the barrier layer, performing a nitrogen treatment.

18. The method of claim 15, wherein the silicon/germanium soaking process is performed using a method selected from the group consisting essentially of thermal treatment, remote plasma treatment, and local plasma treatment.

19. The method of claim 15, wherein the silicon/germanium soaking process is performed in an environment containing a silicon-containing gas.

20. The method of claim 15, wherein the silicon/germanium soaking process is performed in an environment containing a germanium-containing gas.

21. A circuit structure comprising:
a substrate;
a low-k dielectric layer over the substrate;
a conductor in the low-k dielectric layer; and
a silicon/germanium rich layer between the low-k dielectric layer and the conductor.

22. The circuit structure of claim 21, wherein the conductor comprises:
a barrier layer over and contacting the silicon/germanium rich layer; and
a copper-containing line over the barrier layer.

23. The circuit structure of claim 21, wherein the conductor comprises a copper-containing material in contact with the silicon/germanium rich layer.

24. The circuit structure of claim 21 further comprising:
an additional dielectric layer underlying the low-k dielectric layer; and
an additional conductor in the additional dielectric layer, wherein the conductor and the additional conductor are electrically connected, and wherein the silicon/germanium rich layer extends into a region between the conductor and the additional conductor.

25. The circuit structure of claim 21, wherein the silicon/germanium rich layer and the low-k dielectric layer comprise common elements.

26. The circuit structure of claim 21, wherein the conductor comprises a metal line, and a via underlying and adjoining the metal line.

27. The circuit structure of claim 21, wherein the silicon/germanium rich layer is a silicon-rich layer, and is substantially free from germanium.

28. The circuit structure of claim 21, wherein the silicon/germanium rich layer is a germanium-rich layer, and is substantially free from silicon.

29. A circuit structure comprising:
a substrate;
a low-k dielectric layer over the substrate;
an opening in the low-k dielectric layer;
a silicon/germanium rich layer in the opening and contacting the low-k dielectric layer, wherein the silicon/germanium rich layer has a greater silicon concentration than the low-k dielectric layer; and
a copper line in the opening and contacting the silicon/germanium rich layer.

30. The circuit structure of claim 29 further comprising a metallic feature underlying and electrically connected to the copper line, wherein the silicon/germanium rich layer extends into a region between the copper line and the metallic feature.

31. The circuit structure of claim 29, wherein a portion of the silicon/germanium rich layer on a sidewall of the opening comprises at least some of elements of the low-k dielectric layer.

32. The circuit structure of claim 29 further comprising a via in the opening and adjoining the copper line.

33. The circuit structure of claim 29, wherein the silicon/germanium rich layer is a silicon-rich layer, and is substantially free from germanium.

34. The circuit structure of claim 29, wherein the silicon/germanium rich layer is a germanium-rich layer, and is substantially free from silicon.
